(19) United States
(12) Patent Application Publication
(10) Pub. No.: US 2014/0069989 A1
(43) Pub. Date: Mar. 13, 2014

(54) Thin Semiconductor Chip Mounting

(71) Applicant: Texas Instruments Incorporated, Dallas, TX (US)

(72) Inventor: Mutsumi Masumoto, Beppu Oita-Ken (JP)

(21) Appl. No.: 14/024,803

(22) Filed: Sep. 12, 2013

Related U.S. Application Data
(60) Provisional application No. 61/700,477, filed on Sep. 13, 2012.

(51) Int. Cl. H01L 21/50

(52) U.S. Cl. CPC H01L 21/50
USPC 228/180.22; 156/714; 156/498

(57) ABSTRACT

The embodiments of the invention provide a semiconductor chip mounting methods to prevent the occurrence of particles created while mounting a thin semiconductor chip onto a substrate. A semiconductor chip having conductive bumps on its main surface is held by its back via an elastic film using a suction tool having a plurality of suction holes, the semiconductor chip is positioned against a substrate provided with connection wires corresponding to said conductive bumps, and the semiconductor chip is mounted onto the substrate in such a manner that the conductive bumps connect to said connection wires, and uniform pressure is applied from the oversized bonding tool suction to the semiconductor chip via said film while said semiconductor chip is being pressed against said substrate by oversized bonding tool to keep constant pressure in order to bond said conductive bumps with said connection wires. The film assisted bonding tool has a film cooling system to assist in making vacuum holes and a through-hole tool movable relative to the bonding head to create a plurality of holes in said assist film with a plurality of needles.

### CROSS REFERENCE TO RELATED APPLICATIONS

This application claims priority to U.S. Provisional Patent Application No. 61/700,477 file on Sep. 13, 2012. This application is related to U.S. Pat. No. 6,269,999 issued on August 2001 and filed on Aug. 3, 2000.

### BACKGROUND

Embodiments of the invention are directed, in general, to semiconductor chip packaging and, more specifically, mounting a thin semiconductor chip onto a substrate.

A method for mounting a semiconductor chip onto a substrate referred to as flip-chip mounting has been widely adopted. In the case of flip-chip mounting, a body provided with several conductive bumps, that is, bumps usually made of gold, serving as connecting terminals is placed face down onto the surface (referred to as main surface, hereinafter) where circuits are formed on a semiconductor chip, that is, with the main surface facing the substrate, in order to bond said conductive bumps directly to the wires on the substrate.

A semiconductor chip is held by suction using a vacuum suction tool and placed over the area where the bumps are to be mounted onto the wires formed on the substrate. When bonding the gold bumps onto the wires, a fixed amount of pressure is applied to the semiconductor chip using a suction tool, and the substrate is heated at the same time.

In order to apply pressure via said suction tool to the semiconductor chip, it is important to bring the suction tool and the semiconductor chip into close contact by means of vacuum suction. However, a minute gap may be created between the suction surface of the suction tool and the back of the semiconductor chip placed against the suction surface, resulting in a drop in suction power. This drop in suction power not only reduces the pressure applied to the bumps but also creates another problem.

That is, when the suction power of the suction tool drops, the semiconductor chip can no longer follow the pressure applied to the tool, resulting in the problem that tip of the suction tool ends up abrading the surface of the semiconductor chip due to friction. Some of the scraped-off fine silicon particles stick to the back of the semiconductor chip, land on the substrate, and may even be incorporated into a device eventually.

The particles stuck to the semiconductor chip have potential for causing serious problems depending on the ultimate use of the semiconductor chip. For example, a preamplifier bare chip to be mounted on an actuator in a hard disk device may be mentioned. Said scraped-off particles (they are 0.1-5 μm or so in size) stuck to the semiconductor chip come loose inside the device due to vibrations caused by revolution of the magnetic disk and ultimately fall onto the disk. Because the magnetic head floats at a distance of 50 μm or less from the disk surface, said scraped-off particles on the disk seriously affect the function of the hard disk drive.

As a result, with either elastic film, not only was the same bonding strength as that of the conventional example secured, but also the creation of particles due to abrading of the semiconductor chip was avoided entirely.

However, elastic film is effective to prevent mechanical damage on silicon chip by ultrasonic vibration but heat transfer is low when bonding tool is heated up to accelerate bump bonding.

### BRIEF DESCRIPTION OF THE DRAWINGS

Having thus described the invention in general terms, reference will now be made to the accompanying drawings, which are not necessarily drawn to scale, and wherein:

FIG. 1 is an oblique view showing an example of prior art bonding tool.

FIG. 2 shows a possible thermocouple position problem with prior art between the die edge and die center.

FIG. 3 is two graphs showing a temperature GAP cause by the prior art bonding tool.

FIG. 4 shows lack of constant pressure when the semiconductor is thin.

FIG. 5 is a diagram showing an oversized bonding tool overlapping semiconductor chip.

FIG. 6 is a profile view of new tool and comparison with prior art tool.

FIG. 7 is a flowchart illustrative of the steps in the process of thin semiconductor chip mounting in accordance with an embodiment of the invention.

FIG. 8 shows a film cooling system to make vacuum hole by air spray in accordance with an embodiment of the invention.

FIGS. 9A-9C shows tension control during vacuum and bonding.

FIG. 10, comprising FIGS. 10a and 10b, shows prior art single vacuum hole.

FIG. 11, comprising FIGS. 11a and 11b, shows the new bonding tool vacuum hole designs.

FIG. 12 shows the alignment between the semiconductor chip 632 and the substrate 633.

FIG. 13 shows bonding stage design in accordance with embodiment of the invention to reduce temperature GAP.

FIG. 14 shows heat tool attachment and heat shield in accordance with embodiment of the invention to reduce temperature.

FIG. 15 shows tape peeling in accordance with embodiment of the invention.

### DETAILED DESCRIPTION

The invention now will be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. One skilled in the art may be able to use the various embodiments of the invention.

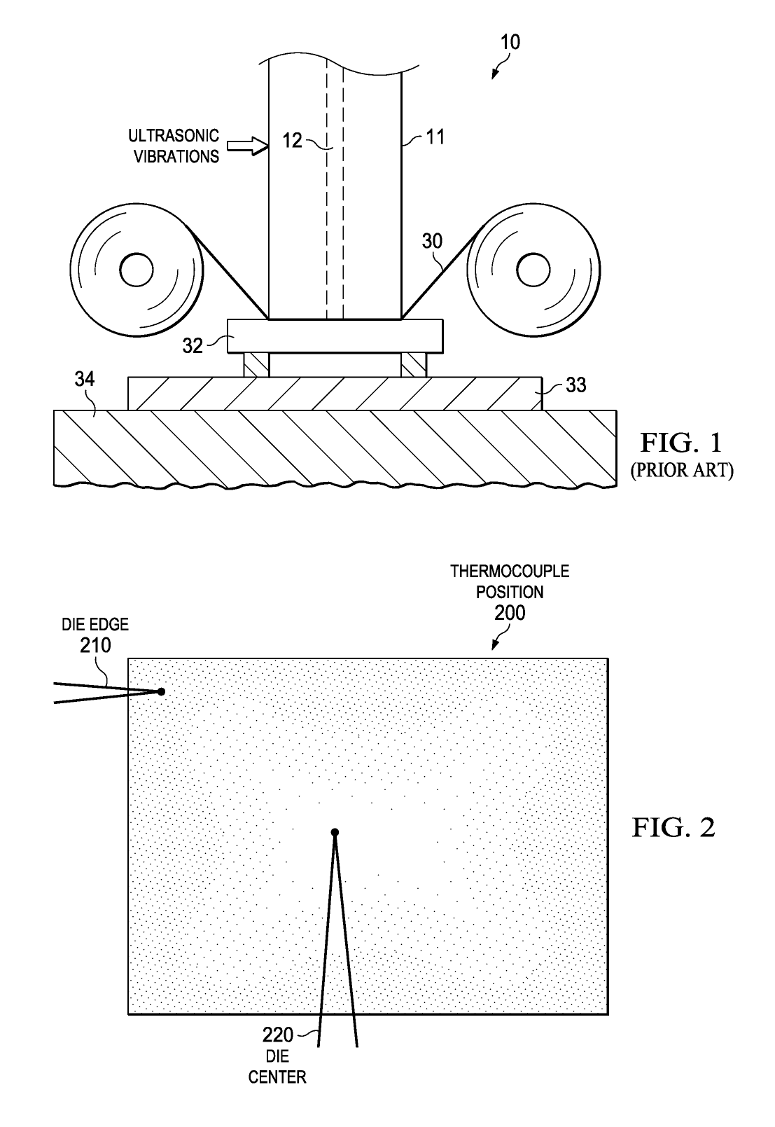

FIG. 1 shows a prior art suction tool. The suction tool is one of the constituents of a device, such as a flip-chip tape assisted bonding device 10, used to mount a semiconductor chip onto a substrate. The bonding tool 11 has a suction nozzle 12 whose tip constitutes a suction surface for the semiconductor chip. The semiconductor chip is held onto said suction surface by means of vacuum suction achieved by the suction power obtained through a single suction hole at the tip of the suction nozzle. In the prior art, an ultrasonic horn for supplying ultrasonic vibrations is connected halfway up the suction nozzle 12. The ultrasonic horn supplies lateral vibrations of a specific frequency to the suction nozzle 12 for a prescribed period of time. The tip of the suction nozzle 12 and ultimately the semiconductor chip held there by means of vacuum suction are vibrated microscopically in the lateral direction by said vibrations. The semiconductor chip is bonded to the substrate by said vibrations, pressure, and heat.

Elastic film 30 is configured as a long tape-like shape and is taken up on a winding reel from a feeding reel. The elastic film is positioned between the suction surface of the suction nozzle 12 and the semiconductor chip when the ultrasonic vibrations are applied to the semiconductor chip via said bonding tool 11. The intervention by the elastic film prevents the semiconductor chip from coming into direct contact with the suction nozzle, so that the back of the semiconductor chip will not be abraded by the suction surface. The suction nozzle 12 is moved to the position where a through-hole tool is provided while the film 30 is carried along in front of said suction nozzle. The through-hole tool contains a needle pin with a sharp tip whereby a hole is created in the film 30 at the position corresponding to the suction hole on the suction nozzle 12. A semiconductor chip 32 held by suction by the suction nozzle 12 is carried onto a substrate 33 fixed onto a mount 34.

In the elastic film feeder device, said tape-like film is mounted onto the device in such a manner that it is positioned in front of the suction surface 11a of the suction nozzle. Every time the step of mounting a semiconductor chip onto the substrate begins, the feeder device drives said reel in such a manner that a new surface of the film is supplied to the front of said suction surface. Although the present invention is not restricted by any specific configuration of the feeder device, it is preferred that the feeder be fixed to said suction tool.

The elastic film which must be capable of efficiently apply pressure to the thin semiconductor chip. The strength to stand up to pressure and thermal tolerance are needed. The thickness of the elastic film, which the inventor has confirmed through experiments to meet these requirements, falls into a range of 10-50 μm. Furthermore, the distance the suction nozzle travels 0.5-1.5 μm or so. In addition, fluororesin (elasticity: approximately 1.7 MPa) and straight chain type polyimide resin (elasticity: approximately 6370 MPa) were found to be suitable as the material of said film.

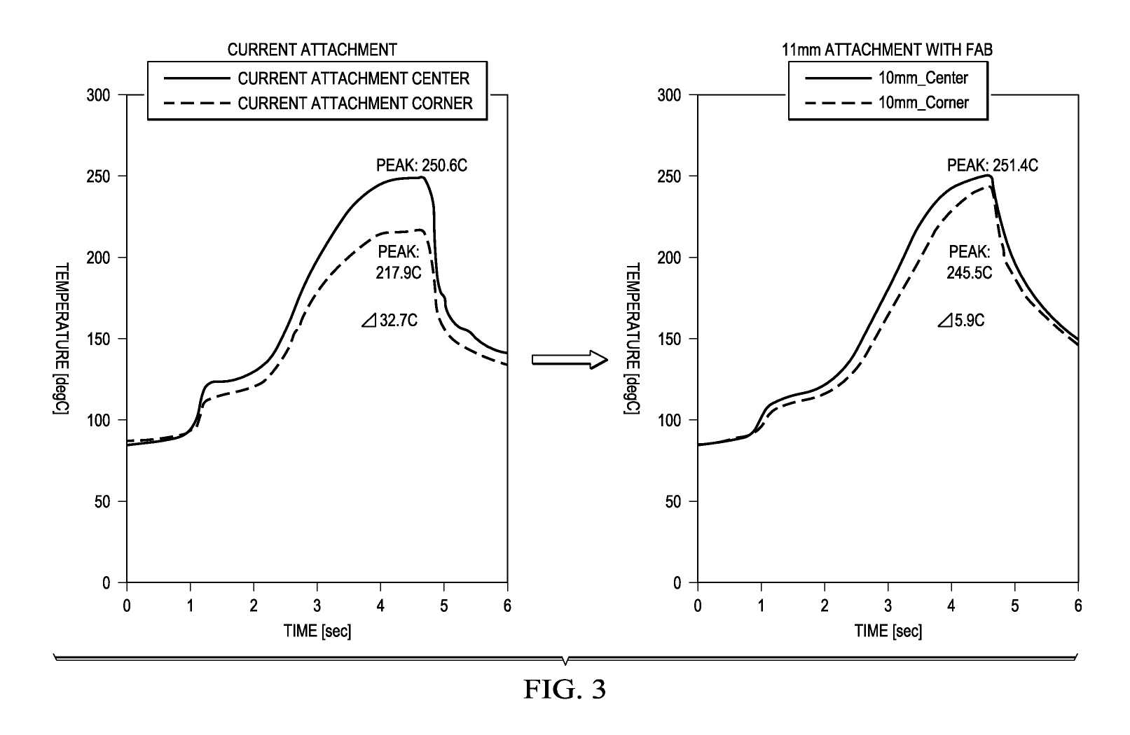

A problem with the prior art bonding tool is a temperature gap. FIG. 2 shows a possible thermocouple position problem between the die edge 210 and die center 220. FIG. 3 are two graphs showing a temperature gap cause by the prior art bonding tool. The temperature profile comparison between the two graphs confirms that there is temperature gap between die center and die corner by using a larger attachment to bonding tool compared with the prior art attachment. 10 mm attachment is used for the comparison.

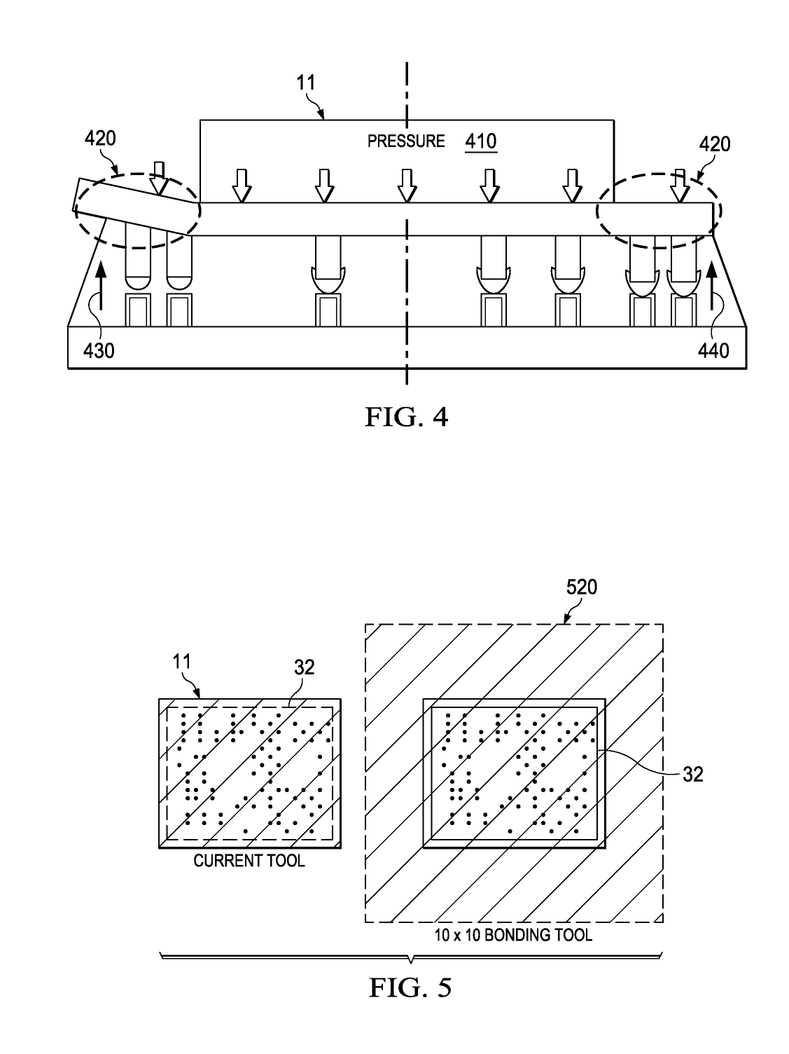

Another problem with the prior art bonding tool is uneven pressure applied to the semiconductor chip. This causes a breakage problem for thin semiconductor chips. FIG. 4 shows lack of constant pressure when the semiconductor is thin. Bonding tool 11 applies pressure 410. During flipichip bonding, peripheral bump contact pressure is lost due to thin die. Prior art bonding tool 11 is too small. Chip edge to bump edge is around 200 um in the example. Loss of pressure due to thin chip is show at points 420. Many bump count is high pressure by reaction force, especially after non-conductive paste NCP hardening 430. Low density bond finger is not much reaction force compare with high density bond finger 440. Table 1 shows size difference between a typical chip and prior art chip vacuum attachment size.

TABLE I

| | X (mm) | Y (mm) |
|---|---|---|
| Chip | 5.92 | 5.05 |
| Chip Vacuum Attachment | 5.466 | 4.601 |
| Difference | 0.454 | 0.449 |

FIG. 5 is a diagram showing an oversized bonding tool 520 overlapping semiconductor chip. Prior art bonding tool is not enough size to do flat bonding. 10 mm×10 mm bonding tool used as example compared with current bonding tool. In the prior art, the bonding tool 11 was sized for the semiconductor chip 32. Embodiments of the invention use a bonding tool sized larger than the semiconductor chip 32. The oversized bonding tool keeps constant pressure, reduces the temperature gap and provides for a universal bonding tool, which will not need to be changed for different chip sizes.

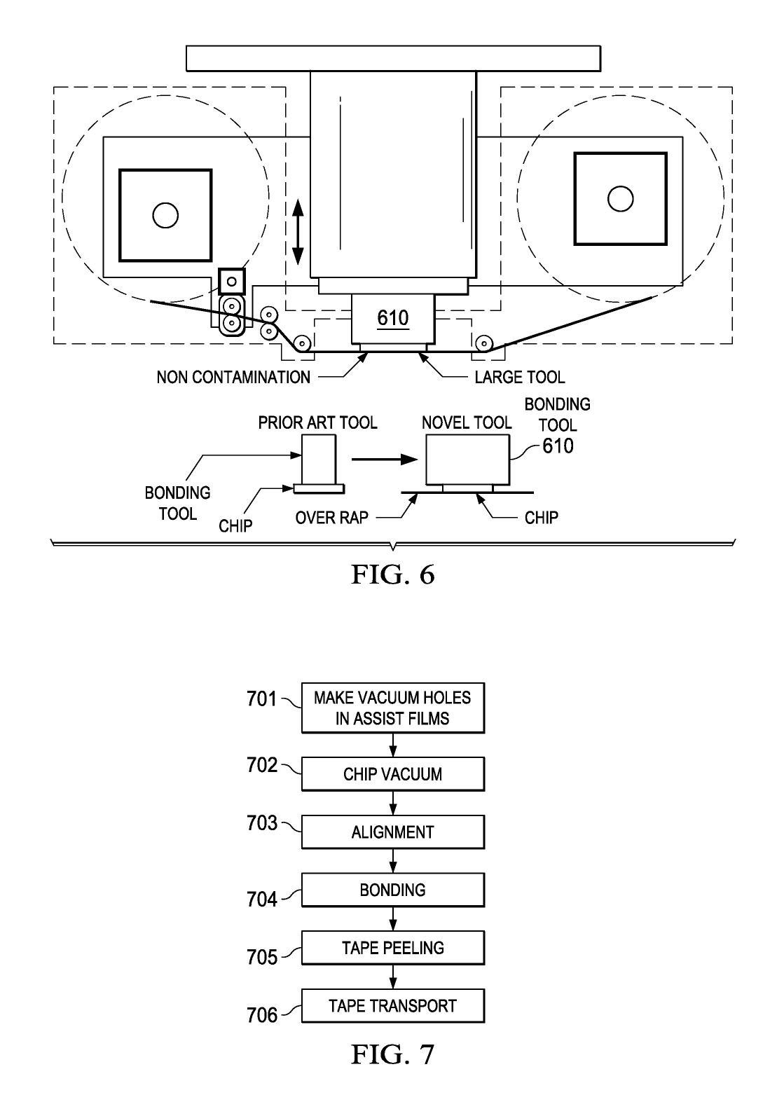

FIG. 6 is a profile view of new bonding tool 610 and comparison with prior art tool. The bonding tool 610 is oversized. The bonding tool 610 may be constructed as part of a new machine or as an attachment to preexisting machine.

FIG. 7 is a flowchart illustrative of steps in the thin semiconductor chip mounting method 700 in accordance with an embodiment of the invention. In Step 701, a plurality of vacuum holes are made into the assist film 810. Assist film is of similar properties as elastic film of the prior art. Not only elastic film, but metal film could also be used to improve heat transfer from bonding tool 610 to silicon die. Metal film is for example, aluminum, copper or steel. Thickness of the metal foil should have enough peel strength for rewind motion. Elastic film including metal particles is another option to have both features of elasticity and good thermal conductivity.

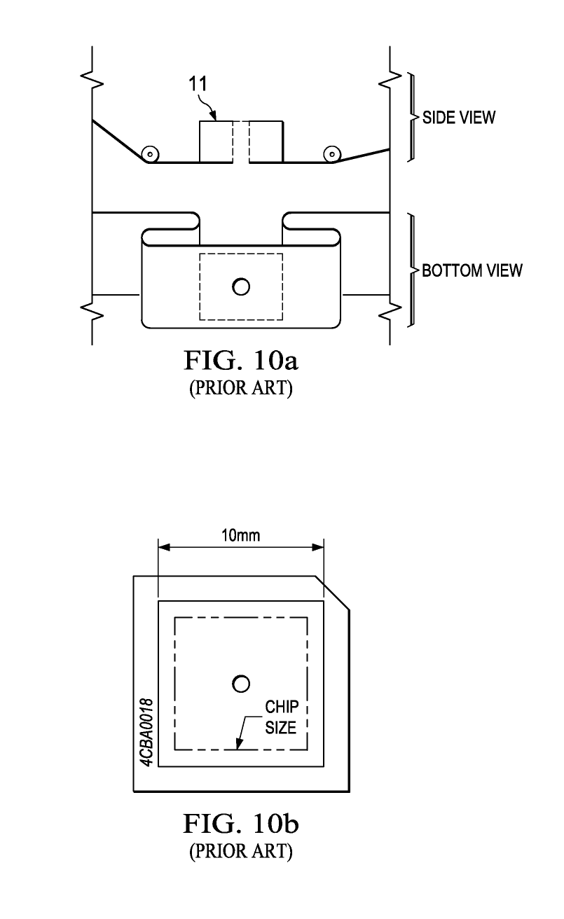

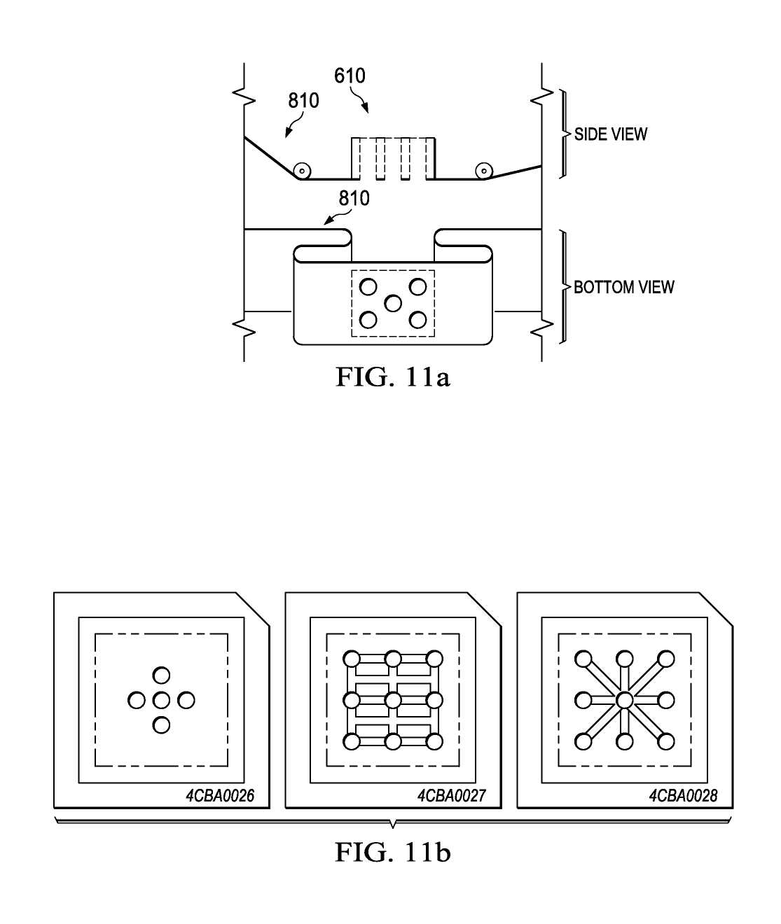

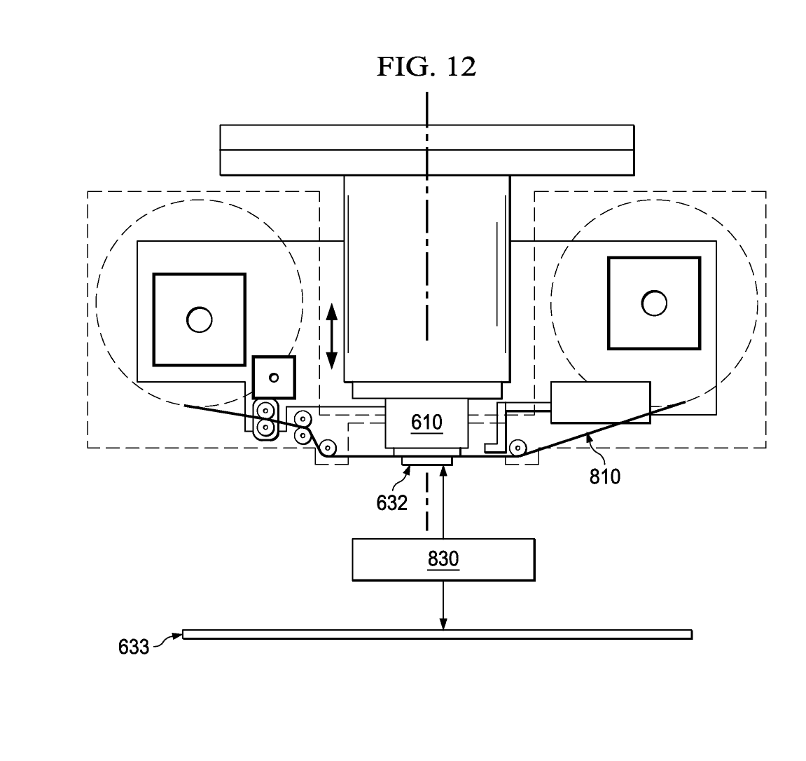

In the next step 702, a vacuum is provide to handle chip. The bonding tool 610 is moved to the position to which a semiconductor chip 632 is supplied. The suction is activated in order to hold the semiconductor chip 632 by means of vacuum suction. Although the assist film 810 is positioned between the bonding tool 610 couple to suction and the semiconductor chip 632, the suction power of the bonding tool 610 couple to suction is transmitted to the semiconductor chip 332 through the holes created in the assist film 810 in the previous step. As a result, not can only the semiconductor chip 632 be held by suction, but also the suction surface can be prevented from coming into direct contact with the semiconductor chip 632. A single hole was used in the prior art tool, however, the single hole is not possible with thin semiconductor chips due to breakage problem. Therefore, new hole patterns are provided to provide increase vacuum power in a more distributed fashion, details in FIGS. 11a and 10b.

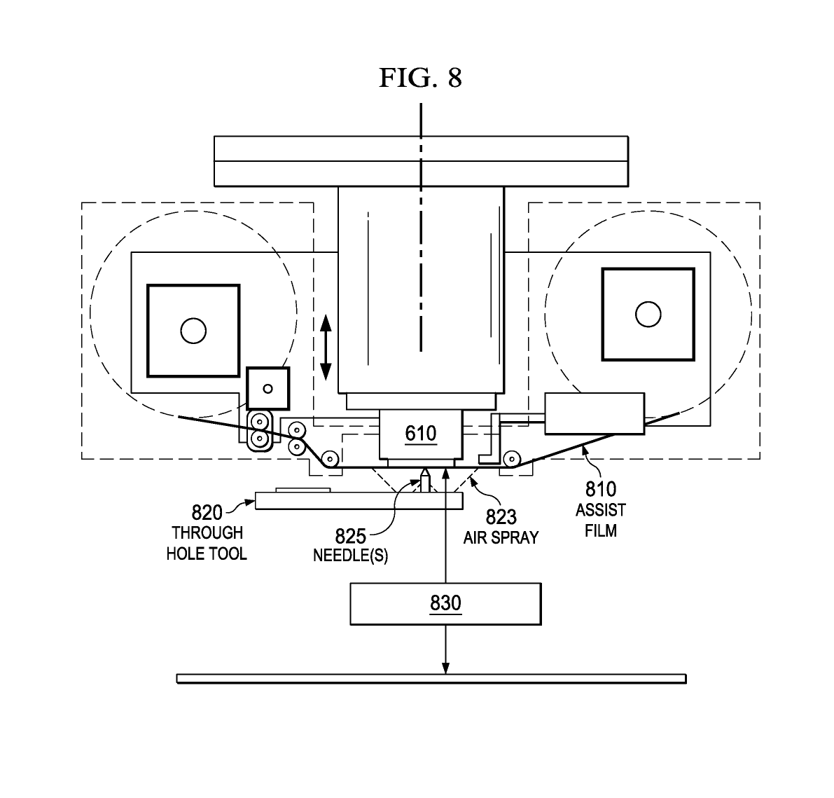

In the preferred embodiment, a film cooling system on a through-hole tool 820 makes the vacuum holes as is shown in FIG. 8 by air spray 823. The air spray 823 is for the cooling of the assist film. Bonding tool 610 movable coupled to a suction nozzle such as 12 or the through-hole tool 820 is moved relative to the other in order to create a plurality of holes in the assist film 810 with one or more needle(s) 825. In such a case, it is desirable to bring the assist film 810 into contact with the suction surface in order to prevent the position of the film from shifting relative to the suction surface after the holes are created, and to apply a fixed level of tension to the assist film 810. Bonding tool 610 may coupled to a single suction nozzle such as that of prior art 12 or suction source may be channeled through a manifold to several holes in bonding tool 610 matched to through-hole tool 820. The final part of a bonding tool that holds the semiconductor chip via suction through the suction holes may be referred to as a bonding head.

An imaging unit 830 is used in alignment as is disclosed below and to recognize/identify semiconductor chip and substrate. An example imaging unit is a charged-coupled device CCD camera.

An alternative embodiment comprises: 1) rolling out/sending the film to the bonding tool 610, 2) moving the through hole tool 820 under the bonding tool 610, 3) downing the bonding tool 610 toward the through hole tool 820 with the air spray 823, 4) moving the bonding tool 610 to the original position, and 5) moving the through hole tool 810 to the original position.

In the next step 702, the bonding tool 610 with suction is moved to the position to which a semiconductor chip 632 is supplied. The suction tool is activated in order to hold the semiconductor chip 632 by means of vacuum suction. Although the assist film 810 is positioned between the bonding tool 610 and the semiconductor chip 632, the suction power of the suction tool is transmitted to the semiconductor chip 632 through the holes created in the film 810. As a result, not can only the semiconductor chip 632 be held by suction, but also the suction surface can be prevented from coming into direct contact with the semiconductor chip 632.

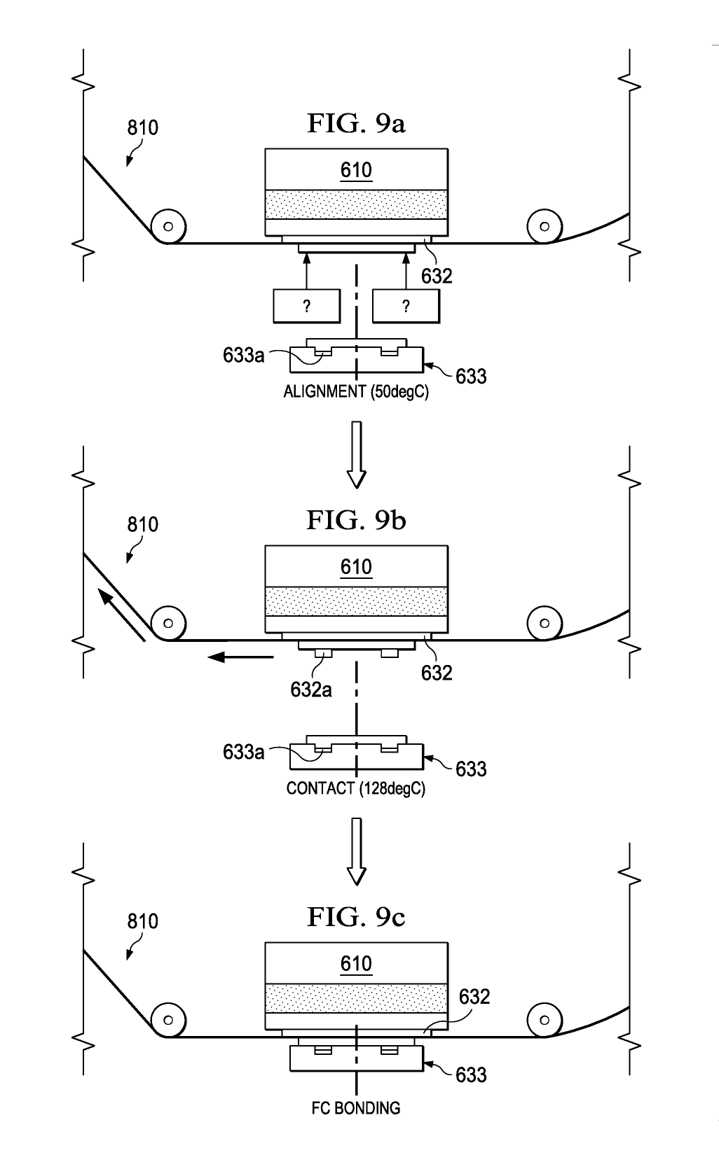

In order to increase vacuum power and distribute the vacuum power to avoid stress points of thin semiconductor chip and miss alignment, a novel vacuum hole design is provided. A single hole was used in the prior art tool, however, the single hole is not possible with thin semiconductor chips due to breakage problem. FIGS. 9A-9C shows tension control during vacuum and bonding.

FIG. 10 shows the prior art single hole for vacuum suction. This single hole design does not provide enough suction and results in a stress point which may break a thin semiconductor chip.

FIG. 11, comprising FIGS. 11a and 11b, shows the new bonding tool vacuum hole designs. The novel designs result in more suction and distributed suction power to control suction at different positions on the chip. The bonding tool 610 include multiple holes and manifold to distribute suction power. The distribution of the suction may also be in places in machine apart from the bonding tool 610 with multiple nozzles coupled to multiple holes in bonding tool 610. FIG. 11a shows an X pattern design in assist film 810. FIG. 11b shows an assortment of vacuum hole patterns as examples. Other patterns are deem to be in the spirit and scope of the embodiments of the invention.

Alignment is provided in step 703. Bonding is provided in step 704. FIG. 9 shows tension control of film for miss alignment. Torque control system is shown for assist film 810 shrinkage tension during temperature GAP between alignment time for miss alignment and contact temperature.

The semiconductor chip 632 held by suction by the suction nozzle is carried onto a substrate 633, where it is to be mounted and positioned there. That is, gold bumps 632a on the semiconductor chip 632 are aligned with wires 633a on the substrate 633. The bonding tool 610 with semiconductor chip 632 held by suction is lowered to bring them into contact. At this time, the bonding tool 610 applies a prescribed amount of pressure in order to press the semiconductor chip 632 against the substrate 633. The substrate 633 is heated to a prescribed temperature. The substrate 633 may also be sealed into the package together with the semiconductor chip. Torque control system is used on assist film 810 to control tension and shrinkage during temperature GAP between alignment time for miss alignment.

FIG. 12 shows the alignment between the semiconductor chip 632 and the substrate 633. The alignment is assisted by use of the imaging unit 830. The imaging unit is positioned between the chip 632 and the substrate 633.

New material in addition to the design may reduce temperature GAP if used as a mount. Photoveel® is a high performance machinable ceramic with high strength and low thermal expansion. This material and the like materials may be used to create a heat shield. Alumina is used in the prior art and has a thermal conductivity of 30 W/mK. The thermal conductivity of Photoveel® is 1.7 W/mK.

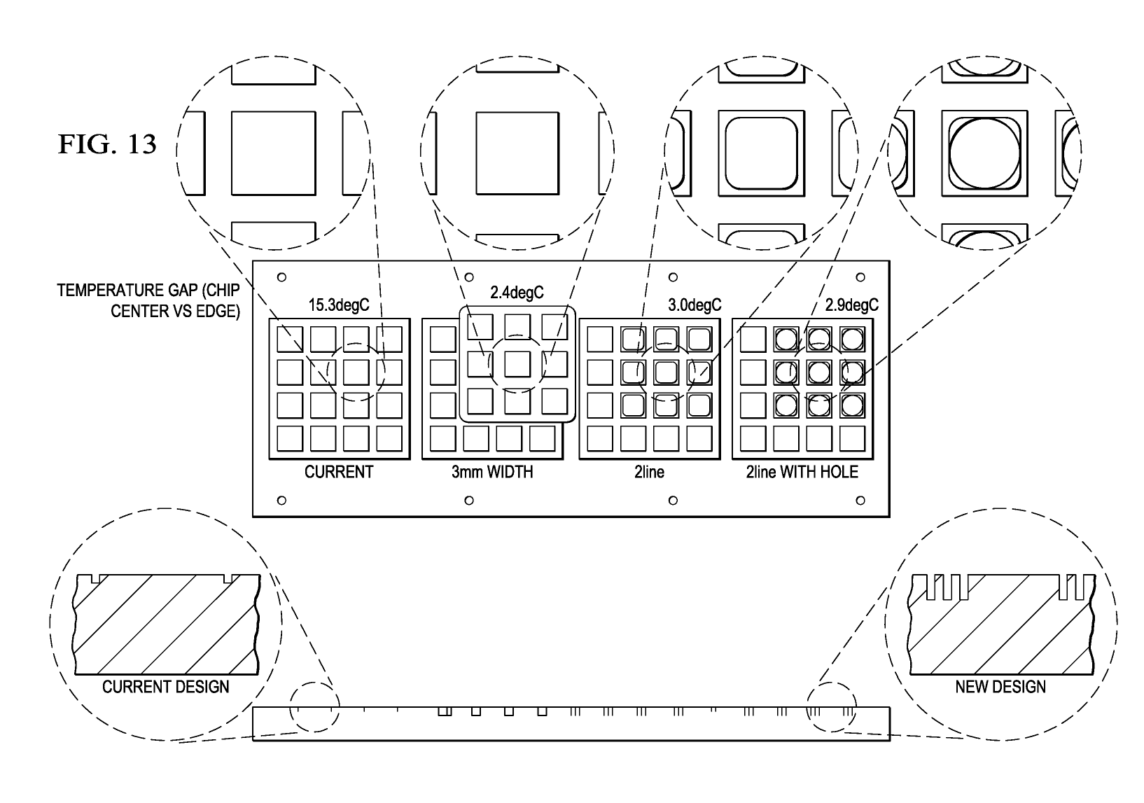

FIG. 13 shows bonding stage design in accordance with embodiment of the invention to reduce temperature GAP.

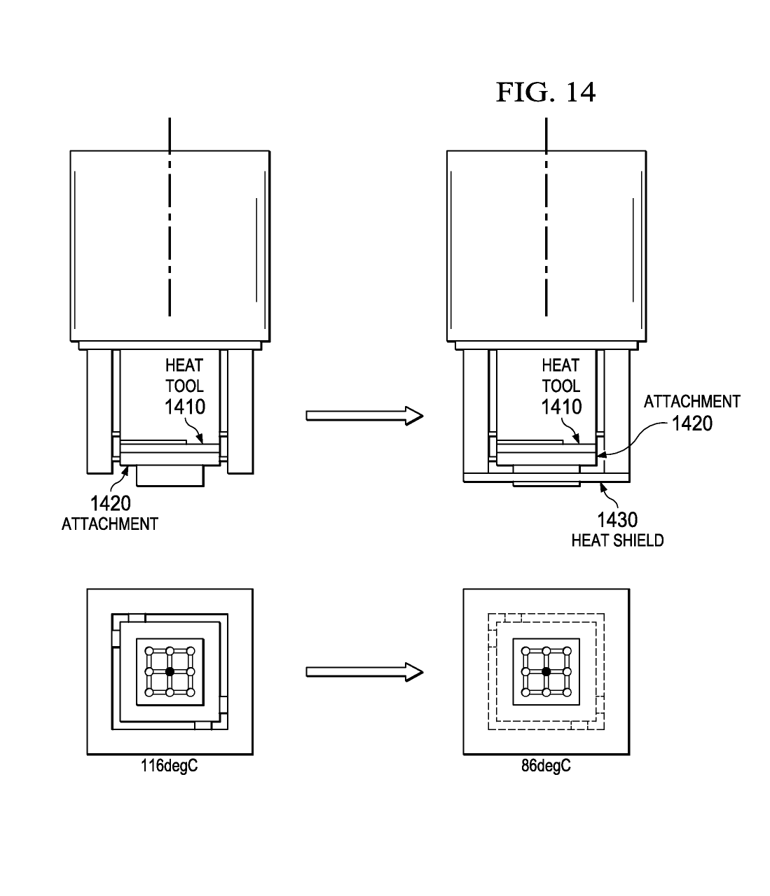

FIG. 14 shows heat tool 1410 and attachment 1420 used in the prior art. The temperature in prior art may reach 116 degrees C. A heat shield 1430 in accordance with embodiment of the invention may be used to reduce temperature cause by radiation heating. In the example, the temperature with heat shield 1430 may be only 86 degrees C.

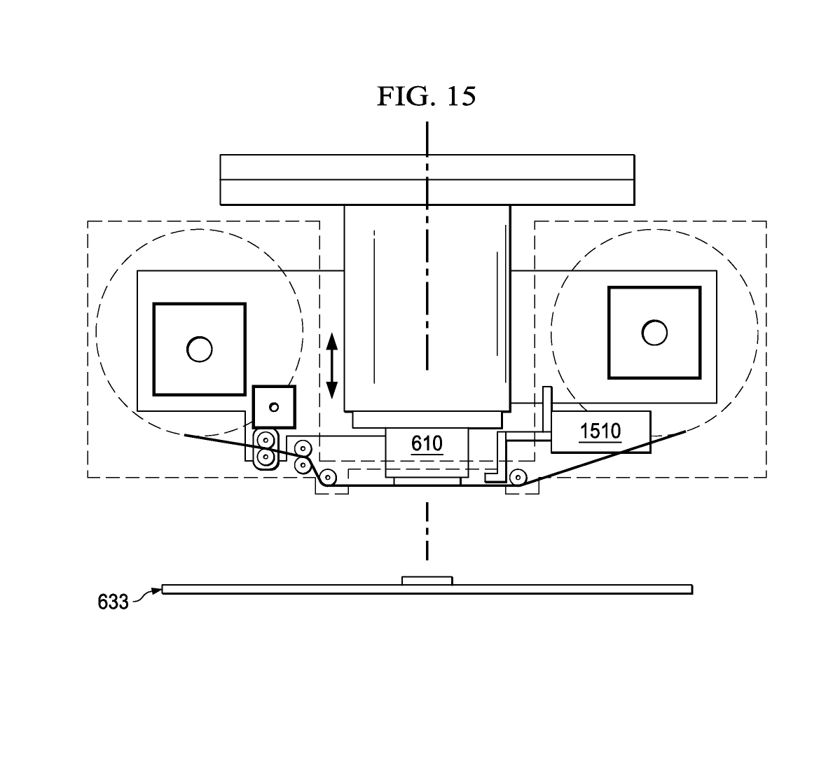

Tape peeling is provided in step 705. FIG. 15 shows tape peeling in accordance with embodiment of the invention. Assist film remover 1510 peels assist film from the semiconductor chip.

Tape transport is provided in step 706. Assist film 810 in FIG. 8 is taken up by a reel as a feeder device is driven, and a new film surface is supplied to the front of the bonding tool 610 coupled to suction.

Many modifications and other embodiments of the invention will come to mind to one skilled in the art to which this invention pertains having the benefit of the teachings presented in the foregoing descriptions, and the associated drawings. Therefore, it is to be understood that the invention is not to be limited to the specific embodiments disclosed. Although specific terms are employed herein, they are used in a generic and descriptive sense only and not for purposes of limitation.

What is claimed is:

1. A method for mounting a semiconductor chip having conductive bumps serving as connecting terminals on a first surface using film assisted bonding, said method comprising:
providing a bonding tool sized larger than said semiconductor chip, said bonding tool coupled to a vacuum source;
providing an unused area elastic assist film from a spool of assist film;
creating a plurality of suction holes in a section of said elastic assist film;
holding said semiconductor chip by a second surface via suction through said plurality of suction holes in said elastic assist film;
positioning said semiconductor chip against a substrate provided with connection wires corresponding to said conductive bumps;
applying pressure from said oversized bonding tool to said semiconductor chip via said elastic assist film while said semiconductor chip is being pressed against said substrate in order to bond said conductive bumps with said connection wires.

2. The method according to claim 1, wherein said film is shaped like a long tape, and an unused area of said film is fed into the space between said bonding tool and the back of said semiconductor chip every time a new semiconductor chip is mounted.

3. The method according to claim 1, wherein the plurality of suction holes on said film are shaped by said oversized suction bonding tool.

4. The method according to claim 1, wherein the plurality of suction holes on said film are shaped by a plurality of shaped needles in said oversized suction bonding tool.

5. The method according to claim 1, wherein the plurality of suction holes form a pattern.

6. The method according to claim 5, wherein the pattern is a square pattern.

7. The method according to claim 5, wherein the pattern is a star pattern.

8. The method according to claim 5, wherein the pattern is a cross pattern.

9. The method according to claim 5, wherein the pattern is an X pattern.

10. A method for peeling a semiconductor chip from a film from a film assisted bonding tool, said method comprising:
moving a plurality of lift up sliders from a first plurality of areas and towards a second area of the semiconductor chip.

11. The method according to claim 10, wherein the second area is a center of the semiconductor chip.

12. The method according to claim 10, wherein the first plurality of areas are the corners of the semiconductor chip.

13. The method according to claim 1, wherein said film is shaped like a long tape, and an unused area of said film is fed into the space between said bonding tool and the back of said semiconductor chip every time a new semiconductor chip is mounted.

14. A film assisted bonding tool mechanism for bonding a semiconductor chip to a substrate, comprising:
a bonding head sized larger than said semiconductor chip, said bonding tool coupled to a vacuum source;
a film cooling system to assist in making vacuum holes in a section of assist film by a spray; and
a through-hole tool movable relative to the bonding head to create a plurality of holes in said assist film with a plurality of needles.

15. A film assisted bonding tool mechanism of claim 14 further comprising a part to provide tension.

16. A film assisted bonding tool mechanism of claim 14 further comprising a part to peel said film from said semiconductor chip.

17. A film assisted bonding tool mechanism of claim 16, wherein said part to peel said film from said semiconductor chip comprising a plurality of sliders.
